(19) United States
(12) Patent Application Publication
(10) Pub. No.: US 2005/0186344 A1
(43) Pub. Date: Aug. 25, 2005

(54) Method and apparatus for synthesizing diamond, electrode for diamond synthesis, and method for manufacturing the electrode

(75) Inventors: Yoshiki Takagi, Tokyo (JP); Yoshihisa Suda, Fujioka-shi (JP); Osamu Shimizu, Fujioka-shi (JP); Kunitaka Yamada, Fujioka-shi (JP)

Correspondence Address: FOLEY AND LARDNER;SUITE 500, 3000 K STREET NW, WASHINGTON, DC, 20007, US

(73) Assignee: MITSUBISHI PENCIL CO., LTD.

(21) Appl. No.: 11/059,334

(22) Filed: Feb. 17, 2005

(30) Foreign Application Priority Data
Feb. 19, 2004 (JP) 2004-042760

(51) Int. Cl. C23C 16/00

(52) U.S. Cl. 427/249.1; 118/723 E

(57) ABSTRACT

A method for synthesizing diamond is provided that can form a thin film of synthetic diamond even on an amorphous substrate such as a glass substrate. Electrodes, each formed from a composite carbon material comprising amorphous carbon and carbon powder uniformly dispersed therein, are placed in a hydrogen atmosphere, and a spark is produced between the electrodes, causing the carbon to sublime and deposit on a silicon substrate.

### BACKGROUND OF THE INVENTION

1. Field of the Invention

The present invention relates to a method and apparatus for synthesizing diamond, an electrode for diamond synthesis, and a method for manufacturing the electrode, and more particularly to diamond synthesis that can form a thin film of synthetic diamond or a particulate diamond, for example, even on an amorphous substrate such as a glass substrate.

2. Description of the Related Art

Diamonds, because of their excellent wear resistance, extreme hardness, and high thermal conductivity, are used as various kinds of functional materials. For example, diamonds are used in machine tools and cutting tools by utilizing their excellent wear resistance and extreme hardness. Further, diamonds are used in heat sinking applications by utilizing their high thermal conductivity, and they are also used in electronic devices by utilizing their semiconducting properties.

A vapor-phase synthesis process is known for forming a thin film of synthetic diamond on a substrate. The prior known vapor-phase synthesis process for synthetic diamond thin films has been the so-called “flow” system in which the source gas is introduced into a reactor, while exhausting the reactant gas at the same time. With this method, thin films of synthetic diamond have been formed only on substrates that allow the diamond to be formed very easily thereon, because the strong gas flow occurring during the synthesis hampers stable synthesis of the diamond. Substrate materials capable of forming synthetic diamond thin films thereon by the prior known synthetic diamond thin film synthesis method are semiconductors such as silicon, metals such as molybdenum and tungsten, and single-crystals such as sapphire. With the prior known method, thin films of synthetic diamond cannot be formed on ceramic substrates or amorphous materials such as glass. If a diamond thin film could be formed on a glass substrate having a wide range of applications as an optical material, the thin film could function as an extremely effective protective film because of its excellent wear resistance, and the range of its applications for lenses, etc. will expand greatly. Furthermore, there is a good possibility that the heat dissipation problem, which has impeded applications to liquid crystal display panels where high integration is needed, can be solved if a coating of artificial diamond, having the best thermal conductivity of all materials, can be formed on a glass substrate.

### SUMMARY OF THE INVENTION

It is an object of the present invention to provide a method for synthesizing diamond that can form thin films of synthetic diamond on substrates of various materials, including an amorphous substrate such as a glass, and a synthesizing apparatus for accomplishing such a method; it is also an object of the invention to provide an electrode for diamond synthesis and a method for manufacturing the same.

According to the present invention, there is provided a method, of synthesizing diamond, comprising the steps of placing a pair of closely spaced electrodes, at least one of which is formed from a composite carbon material, and producing a spark between the two electrodes, to thereby cause the carbon to sublime and deposit.

Preferably, the spark is produced between the electrodes in a thin hydrogen atmosphere.

According to the present invention, there is also provided an apparatus for synthesizing diamond, comprising a pair of closely spaced electrodes at least one of which is formed from a composite carbon material, and a power supply which generates an electric current for producing a spark between the two electrodes.

According to the present invention, there is also provided an electrode for diamond synthesis, comprising amorphous carbon and carbon powder uniformly dispersed through the amorphous carbon.

According to the present invention, there is also provided a method of manufacturing an electrode for diamond synthesis, comprising the steps of mixing carbon powder into a carbon-containing resin, and carbonizing the mixture.

The electrodes are each formed, for example, in the shape of a cylinder, a circular truncated cone, a two-stepped cylinder whose end portion of prescribed length is made smaller in diameter than the remaining portion, a flat-tip screwdriver, a plate, or a coil.

The composite carbon material includes, for example, amorphous carbon and carbon powder uniformly dispersed through the amorphous carbon.

Preferably, the carbon powder is a non-amorphous or crystalline carbon powder, and is a material containing at least one substance selected from the group consisting, for example, of carbon black, graphite, fullerene, carbon nanotubes, carbon nanofibers, and coke.

The carbon-containing resin is, for example, an organic resin material having a three-dimensional cross-linked structure or a natural organic material that carbonizes in a solid phase, and more specifically is a material containing one substance selected from the group consisting of an organic polymeric substance and its monomer, oligomer, or the like, tar, pitch, or the like, carbonized pitch or the like, a prepolymer or the like of a thermoplastic resin or a thermosetting resin, etc. or a mixture of two or more substances selected from the above group.

Here, the organic polymeric substance is a substance other than the thermoplastic resins and thermosetting resins described hereinafter, and is a compound having condensed polycyclic aromatics such as lignin, cellulose, gum tragacanth, gum arabic, natural gum and its derivative, sugars, chitin, chitosan, etc. within its basic molecular structure, or an indanthrene-based vat dye, or its intermediate, that is derived from a formalin condensate of naphthalenesulfonate, dinitronaphthalene, pyrene, pyranthrone, violanthrone, benzanthrone, etc.

Examples of the thermoplastic resin include conventional thermoplastic resins, such as polyvinyl chloride, polyacrylonitrile, polyvinylidene chloride, after-chlorinated polyvinyl chloride, polyvinyl acetate, polyvinyl alcohol, polyvinyl pyrolidone, ethyl cellulose, carboxymethyl cellulose, and polyvinyl chloride-acetate copolymer, and other resins such as polyphenylene oxide, poly-para-xylene, polysulfone, polyimide, polyamide imide, polybenzimidazole, and polyoxadiazole.

Examples of the thermosetting resin include phenol resin, furan resin, epoxy resin, xylene resin, copna resin, etc.

### BRIEF DESCRIPTION OF THE DRAWINGS

FIG. 1 is a diagram schematically showing an apparatus for synthesizing diamond according to the present invention;

FIG. 2 is an SEM photograph of a diamond obtained in a first example;

FIG. 3 is the Raman spectrum of the diamond;

FIG. 4 is an SEM photograph of a diamond obtained in a second example;

FIG. 5 is the Raman spectrum of the diamond; and

FIG. 6 is the Raman spectrum of graphite.

### EXAMPLES

The present invention will be described in further detail below with reference to examples, but it should be understood that the present invention is by no means restricted to the examples described herein.

### Example 1

Twenty-five parts of natural graphite fine powder (with an average particle size of 3 μm, manufactured by Nippon Graphite) were dispersed and mixed into 20 parts of carbonized pitch (KH-1 P, manufactured by Kureha Chemical Industry) and 55 parts of furan resin (VF-303, manufactured by Hitachi Chemical), and the resulting composition was extrusion-molded to obtain rod-shaped moldings, which were then baked at 1000° C. in a nitrogen gas atmosphere, followed by baking at 1400° C. in an argon gas atmosphere, to obtain a cylindrically shaped composite carbon material and a flat-tip screwdriver-shaped composite carbon material.

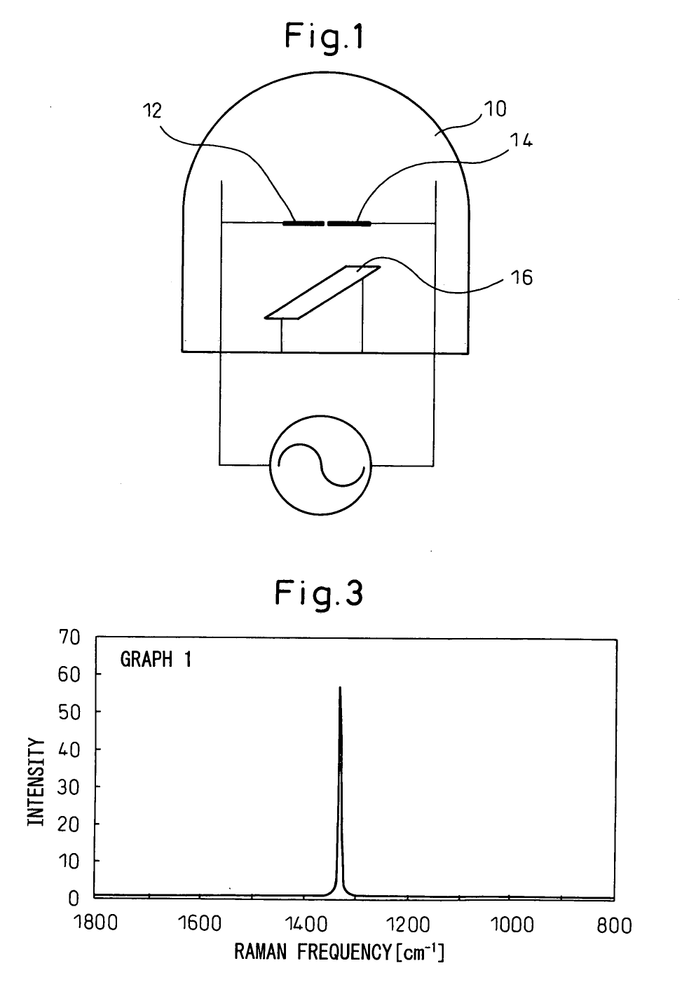

Then, as shown in FIG. 1, the electrode of the cylindrically shaped composite carbon and the electrode of the flat-tip screwdriver-shaped cylindrical composite carbon material were placed as electrodes 12 and 14, respectively, inside a hermetically sealed chamber 10 made of heat resistant glass. A silicon substrate was placed with its direction oriented so as to intersect with the direction along which the electrodes were arranged.

After evacuating the chamber 10, a hydrogen gas was introduced at 100 Torr, and a spark was produced by supplying a 50-Hz AC current of 50 A for 10 seconds; at this time, the electrode temperature was 2300 to 2500° C. while the substrate temperature was 300 to 400° C., and a deposit consisting of particles of particle size 5 μm was obtained on the silicon substrate 16.

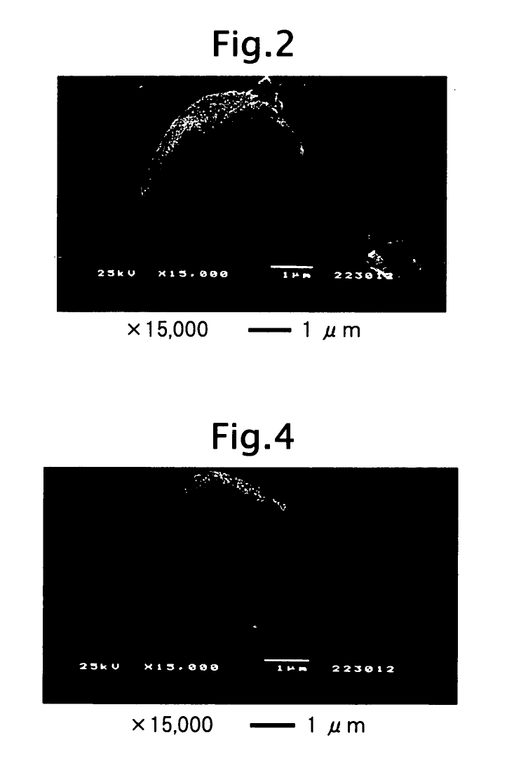

When the deposit was observed under an SEM (Scanning Electron Microscope), a particulate substance was observed as shown in FIG. 2, and the spectrum peculiar to diamond such as shown in FIG. 3 was acquired by Raman spectroscopy; hence, the deposit was identified as diamond.

### Example 2

For 50 parts of chlorinated polyvinyl chloride resin (T-741, manufactured by Nippon Carbide) and 50 parts of natural graphite fine powder (with an average particle size of 5 μm, manufactured by Nippon Graphite), 20 parts of diallyl phthalate monomer as a plasticizer were added, dispersed, and mixed, and the resulting composition was extrusion-molded to obtain a plate-shaped and a circular truncated cone-shaped molding, which were then baked at 1000° C. in a nitrogen gas atmosphere, followed by baking at 1500° C. in a vacuum, to obtain a plate-shaped and a circular truncated cone-shaped carbon-based composite material.

The plate-shaped and the circular truncated cone-shaped carbon-based composite material were used as the electrodes, and a deposit was obtained on the silicon substrate in the same manner as in the first example.

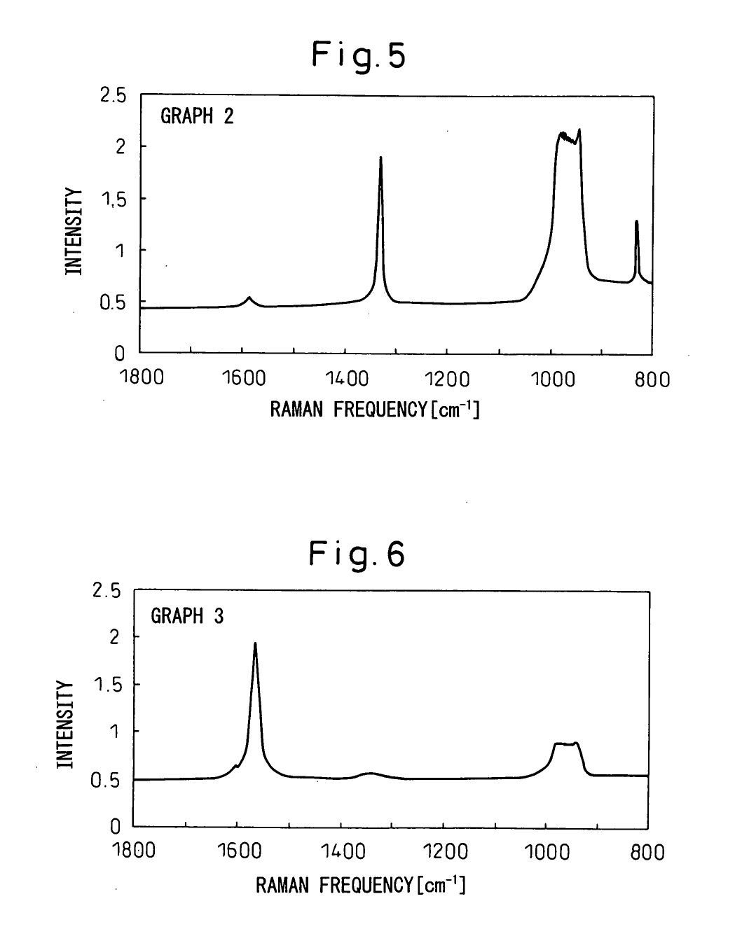

When the deposit was observed under an SEM, a particulate substance was observed as shown in FIG. 4, and the spectrum peculiar to diamond such as shown in FIG. 5 was acquired by Raman spectroscopy; hence, the deposit was identified as diamond.

### Comparative Example

Rod-shaped moldings of a conventional carbon material were used as the electrodes, and a deposit was obtained on the silicon substrate in the same manner as in the first example; however, the spectrum acquired by Raman spectroscopy was one peculiar to graphite as shown in FIG. 6, and the deposit was identified as graphite.

1. A method of synthesizing diamond, comprising the steps of placing a pair of closely spaced electrodes, at least one of which is formed from a composite carbon material, and producing a spark between the two electrodes, to thereby cause the carbon to sublime and deposit.

2. A method of synthesizing diamond according to claim 1, wherein the composite carbon material includes amorphous carbon and carbon powder uniformly dispersed through the amorphous carbon.

3. A method of synthesizing diamond according to claim 2, wherein the carbon powder is a material containing at least one substance selected from the group consisting of carbon black, graphite, fullerene, carbon nanotubes, carbon nanofibers, and coke.

4. An apparatus for synthesizing diamond, comprising a pair of closely spaced electrodes at least one of which is formed from a composite carbon material, and a power supply which generates an electric current for producing a spark between the two electrodes.

5. An apparatus for synthesizing diamond according to claim 4, wherein the composite carbon material includes amorphous carbon and carbon powder uniformly dispersed through the amorphous carbon.

6. An apparatus for synthesizing diamond according to claim 4, wherein the carbon powder is a material containing at least one substance selected from the group consisting of carbon black, graphite, fullerene, carbon nanotubes, carbon nanofibers, and coke.

7. An electrode for diamond synthesis, comprising amorphous carbon and carbon powder uniformly dispersed through the amorphous carbon.

8. An electrode for diamond synthesis according to claim 7, wherein the carbon powder is a material containing at least one substance selected from the group consisting of carbon black, graphite, fullerene, carbon nanotubes, carbon nanofibers, and coke.

9. An electrode for diamond synthesis according to claim 7, wherein the electrode is formed in the shape of a flat-tip screwdriver.

10. A method of manufacturing an electrode for diamond synthesis, comprising the steps of mixing carbon powder into a carbon-containing resin, and carbonizing the mixture.

11. A method of manufacturing an electrode for diamond synthesis according to claim 10, wherein the carbon powder is a material containing at least one substance selected from the group consisting of carbon black, graphite, fullerene, carbon nanotubes, carbon nanofibers, and coke.
